(19) United States
(12) Patent Application Publication
(10) Pub. No.: US 2017/0207049 A1
(43) Pub. Date: Jul. 20, 2017

(54) SYSTEM FOR ACTIVELY DETECTING ALTERNATING CURRENT LOAD

(71) Applicant: PROLIFIC TECHNOLOGY INC., Taipei (TW)

(72) Inventors: Chih-Chin Yang, Taipei (TW); Chia-Chang Hsu, Hsinchu (TW); Yun-Kuo Lee, Hsinchu City (TW)

(73) Assignee: PROLIFIC TECHNOLOGY INC., Taipei (TW)

(21) Appl. No.: 15/344,598

(22) Filed: Nov. 7, 2016

(30) Foreign Application Priority Data
Jan. 19, 2016 (TW) 105101599

(51) Int. Cl. H01H 47/00; G01R 19/175; G01R 19/00

(52) U.S. Cl. CPC H01H 47/002; G01R 19/0092; G01R 19/175

(57) ABSTRACT

A system for actively detecting an alternating current (AC) load includes a first power interface, a second power interface, a switch unit, and a control unit. The first power interface is coupled to an AC source to receive and provide an AC voltage. The second power interface is configured to be coupled to an electronic equipment to provide the AC source to the electronic equipment and provide a connection signal according to whether the electronic equipment is coupled to the second power interface. The switch unit is coupled between the first power interface and the second power interface and receives a switch signal to determine whether the AC voltage is transmitted to the second power interface. The control unit is coupled to the second power interface and the switch unit to provide the switch signal according to the connection signal.

### CROSS-REFERENCE TO RELATED APPLICATION

This application claims the priority benefits of Taiwan application serial no. 105101599, filed on Jan. 19, 2016. The entirety of the above-mentioned patent application is hereby incorporated by reference herein and made a part of this specification.

### FIELD OF INVENTION

The invention relates to an alternating current (AC) system and particularly relates to a system for actively detecting an AC load.

### DESCRIPTION OF RELATED ART

At present, electronic equipment can be found everywhere in a household, and thus plenty of sockets are arranged in the household for complying with the power supply requirements. The normal sockets continuously supply power; hence, when the plugs of the home appliances are plugged into the sockets, sparks may be generated at the sockets on the wall due to voltage difference, and the sparks may lead to accidental fire on the electronics and thus cause an accident. Hence, how to better prevent accidents caused by the sockets has become one of the important issues in terms of home security.

### SUMMARY OF THE INVENTION

The invention is directed to a system for actively detecting an AC load, so as to prevent accidents arising from external power interfaces.

In an embodiment of the invention, a system for actively detecting an AC load includes a first power interface, a second power interface, a switch unit, and a control unit. The first power interface is coupled to an AC source to receive and provide an AC voltage. The second power interface is configured to be coupled to an electrical equipment to provide the AC source to the electrical equipment and provide a connection signal according to whether the electrical equipment is coupled to the second power interface. The switch unit is coupled between the first power interface and the second power interface and receives a switch signal to determine whether the AC voltage is transmitted to the second power interface. The control unit is coupled to the second power interface and the switch unit to provide the switch signal according to the connection signal.

In view of the above, in the system for actively detecting the AC load, when the electronic equipment is coupled to the second power interface, the AC voltage is supplied to the second power interface; when the electronic equipment is not coupled to the second power interface, the AC voltage is stopped from being provided to the second power interface. Thereby, the possibility of getting an electric shock by the second power interface can be reduced.

Several exemplary embodiments accompanied with figures are described in detail below to further describe the invention in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the invention.

FIG. 1 is a schematic diagram illustrating a system for actively detecting an AC load according to an embodiment of the invention.

FIG. 2 is a schematic systematic diagram illustrating a control unit according to an embodiment of the invention.

FIG. 3 is a flowchart illustrating a method of operating a system for actively detecting an AC load according to an embodiment of the invention.

### DETAILED DESCRIPTION OF DISCLOSED EMBODIMENTS

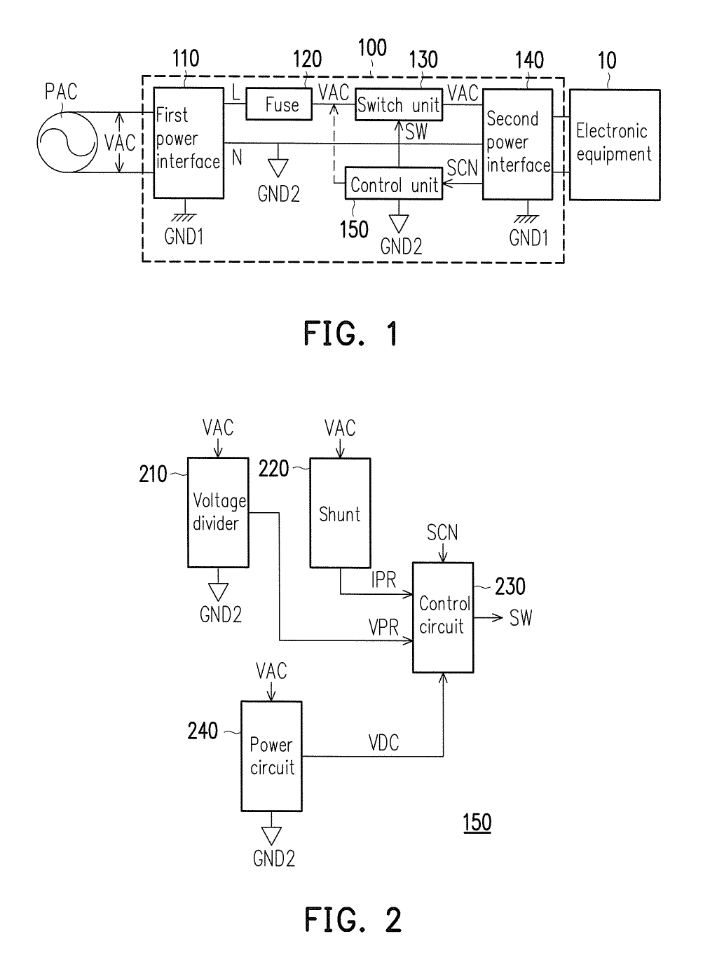

FIG. 1 is a schematic diagram illustrating a system for actively detecting an AC load according to an embodiment of the invention. With reference to FIG. 1, in the present embodiment, a system 100 for actively detecting an AC load includes a first power interface 110, a fuse 120, a switch unit 130, a second power interface 140, and a control unit 150. The first power interface 110 is coupled to the AC source PAC to receive and provide an AC voltage VAC, and the first power interface 110 is coupled to the first ground point GND1 to release static electricity. The AC voltage VAC is transmitted through a firewire L and a ground wire N. The fuse 120 is coupled between the switch unit 130 and the first power interface 110, so as to transmit the AC voltage VAC to the switch unit 130 and restrict the maximum current of the AC voltage VAC.

The switch unit 130 is coupled between the first power interface 110 and the second power interface 140 and receives a switch signal SW to determine whether the AC voltage VAC is transmitted to the second power interface 140. The second power interface 140 is coupled to the first ground point GND1 to release static electricity and is configured to be coupled to an electrical equipment 10 to provide the AC source VAC to the electrical equipment 10 and provide a connection signal SCN according to whether the electrical equipment 10 is coupled to the second power interface 140.

The control unit 150 is coupled to the second power interface 140 to receive the connection signal SCN, is coupled to the switch unit 130 to provide the switch signal SW, and receives the second ground point GND2. To be specific, the control unit 150 determines whether the electronic equipment 10 (i.e., the AC load) is coupled to the second power interface 140 according to the connection signal SCN, i.e., whether the plug of the actively detecting electronic equipment 10 is plugged into the socket of the second power interface 140. When the electronic equipment 10 is coupled to the second power interface 140, the second power interface 140 should supply power to the electronic equipment 10; at this time, the control unit 150 detects a zero-phase point of the AC voltage VAC and switches on the switch unit 130 at the zero-phase point of the AC voltage VAC, so as to reduce the possibility of generating sparks (i.e., electric arcs) by the voltage drop. When the electronic equipment 10 is not coupled to the second power interface 140, the second power interface 140 should stop supplying power; at this time, the control unit 150 switches off the switch unit 130, so as to reduce the possibility of getting an electric shock by the second power interface 140.

The control unit 150 can continuously detect the voltage and the current of the AC voltage VAC, so as to determine whether the circuit between the first power interface 110 and the second power interface 140 becomes abnormal. If the circuit between the first power interface 110 and the second power interface 140 does not become abnormal, the control unit 150 leaves the state of the switch unit 140 unchanged; when the circuit between the first power interface 110 and the second power interface 140 becomes abnormal, the control unit 150 switches off the switch unit 130, so as to prevent the system 100 for actively detecting the AC load from generating accidents.

In the present embodiment, the switch unit 130 can further include a relay to control whether the AC voltage VAC is provided to the second power interface 140; however, in another embodiment, the switch unit may be any type of switch device, which should not be construed as a limitation to the invention. Besides, in the present embodiment, the first power interface 110 and the second power interface 140 are coupled to a first ground point GND1, the control unit 150 is coupled to a second ground point GND2, the first ground point GND1 is different from the second ground point GND2, and the second ground point GND2 is coupled to the ground wire N configured to transmit the AC voltage VAC. Here, the control unit 150 is, for instance, a non-isolating circuit.

According to the actual application environment, the system 100 for actively detecting the AC load can be an outlet arranged on a wall, an extension cord, or a socket dock. That is, the second power interface 140 can be an insertion terminal of the outlet, and the first power interface 110 can be a plug; alternatively, the second power interface 140 can be an insertion terminal of the outlet, and the first power interface 110 can be a circuit terminal of the outlet. Said descriptions are merely exemplary and should not be construed as limitations to the invention.

FIG. 2 is a schematic systematic diagram illustrating a control unit according to an embodiment of the invention. With reference to FIG. 1 and FIG. 2, in the present embodiment, the control unit 150 includes a voltage divider 210, a shunt 220, a control circuit 230, and a power circuit 240. The power circuit 240 receives the AC voltage VAC, converts the AC voltage VAC into a direct current (DC) operating voltage VDC, and provides the DC operating voltage VDC to the control circuit 230.

The voltage divider 210 receives the AC voltage VAC and provides a phase reference voltage VPR. The shunt 220 receives the AC voltage VAC and provides a phase reference current IPR. The control circuit 230 is coupled to the voltage divider 210 and the shunt 220 and receives the connection signal SCN, so as to provide the switch signal SW according to the connection signal SCN, the phase reference voltage VPR, and the phase reference current IPR.

To be specific, the control circuit 230 determines whether the electronic equipment 10 is coupled to the second power interface 140 according to the connection signal SCN and determines the peak, the valley, and the zero-phase point of the wave of the AC voltage VAC through continuously monitoring the variations in the voltage and the current of the AC voltage VAC. If the electronic equipment 10 is not coupled to the second power interface 140, the control circuit 230 switches off the switch unit 130 through the switch signal SW. If the electronic equipment 10 is coupled to the second power interface 140, and the AC voltage VAC is not located at the zero-phase point, the control circuit 230 keeps the switch unit 130 to be switched off If the electronic equipment 10 is coupled to the second power interface 140, and the AC voltage VAC is located at the zero-phase point, the control circuit 230 switches on the switch unit 130 through the switch signal SW. If the switch unit 130 is switched on, and the electronic equipment 10 is continuously coupled to the second power interface 140, the control circuit 230 continuously switches on the switch unit 130 through the switch signal SW.

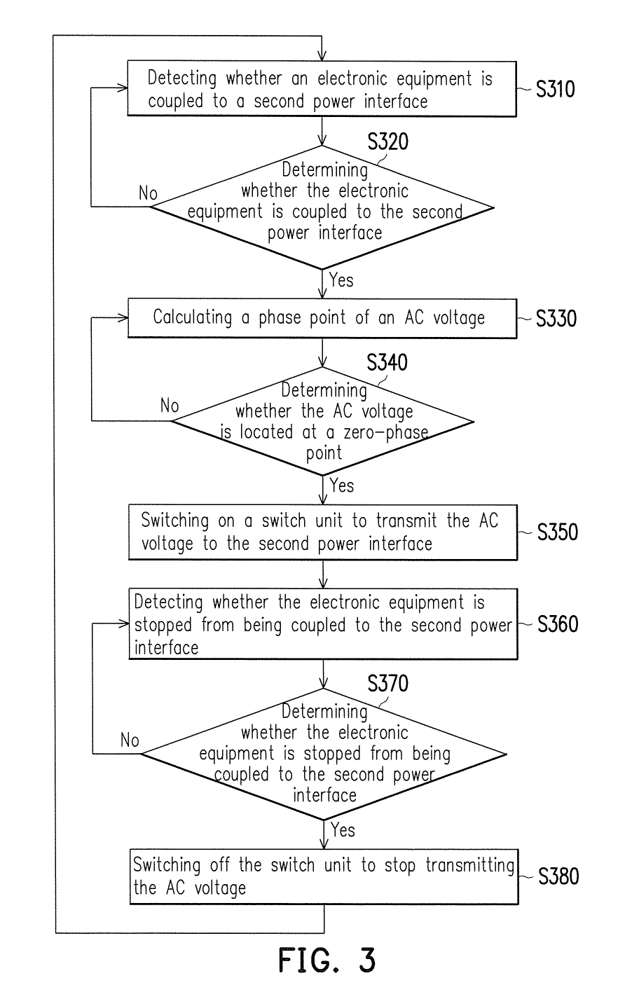

FIG. 3 is a flowchart illustrating a method of operating a system for actively detecting an AC load according to an embodiment of the invention. With reference to FIG. 3, in the present embodiment, the method of operating the system for actively detecting the AC load includes following steps. In step S310, whether the electronic equipment is coupled to the second power interface is detected. In step S320, whether the electronic equipment is coupled to the second power interface is determined. If the electronic equipment is coupled to the second power interface, i.e., if the determination result is “yes”, step S330 is performed; if the electronic equipment is not coupled to the second power interface, i.e., if the determination result is “no”, go back to the step S310.

In step S330, the phase point of the AC voltage is calculated. In step S340, whether the AC voltage is located at the zero-phase point is determined. If the AC voltage is located at the zero-phase point, i.e., if the determination result is “yes”, step S350 is performed; if the AC voltage is not located at the zero-phase point, i.e., if the determination result is “no”, go back to the step S330. In step S350, the switch unit is switched on, so as to transmit the AC voltage to the second power interface. In step S360, whether the electronic equipment is stopped from being coupled to the second power interface is detected. In step S370, whether the electronic equipment is stopped from being coupled to the second power interface is determined. If the electronic equipment is stopped from being coupled to the second power interface, i.e., if the determination result is “yes”, step S380 is performed; if the electronic equipment is stopped from being coupled to the second power interface, i.e., if the determination result is “no”, go back to the step S360. In step S380, the switch unit is switched off, so as to stop transmitting the AC voltage and go back to step S310. The order of the steps S310, S320, S330, S340, S350, S360, S370, and S380 is exemplary and should not be construed as a limitation to the invention. Details of these steps can be found in the previous embodiments shown in FIG. 1 and FIG. 2 and thus will not be further explained hereinafter.

To sum up, in the system for actively detecting the AC load as provided in the embodiment of the invention, when the electronic equipment is coupled to the second power interface, the AC voltage is provided at the zero-phase point of the AC voltage, so as to reduce the possibility of generating sparks (i.e., electric arcs) caused by voltage drop. Besides, if the electronic equipment is not coupled to the second power interface, the AC voltage is stopped from being provided to the second power interface, so as to reduce the possibility of getting electric shock by the second power interface.

Although the invention has been provided with reference to the above embodiments, it will be apparent to one of ordinary skill in the art that modifications to the described embodiments may be made without departing from the spirit of the invention. Accordingly, the scope of the invention will be defined by the attached claims and not by the above detailed descriptions.

What is claimed is:

1. A system for actively detecting an alternating current load, the system comprising:
a first power interface coupled to an alternating current source to receive and provide an alternating current voltage;
a second power interface configured to be coupled to an electronic equipment to provide the alternating current source to the electronic equipment and provide a connection signal according to whether the electronic equipment is coupled to the second power interface;
a switch unit coupled between the first power interface and the second power interface, the switch unit receiving a switch signal to determine whether the alternating current voltage is transmitted to the second power interface; and
a control unit coupled to the second power interface and the switch unit to provide the switch signal according to the connection signal.

2. The system as recited in claim 1, wherein when the electronic equipment is not coupled to the second power interface, the control unit sets the switch signal according to the connection signal to switch off the switch unit.

3. The system as recited in claim 1, wherein when the electronic equipment is coupled to the second power interface, the control unit detects a zero-phase point of the alternating current voltage and switches on the switch unit at the zero-phase point.

4. The system as recited in claim 3, wherein the control unit comprises:
a voltage divider receiving the alternating current voltage and providing a phase reference voltage;
a shunt receiving the alternating current voltage and providing a phase reference current; and
a control circuit coupled to the voltage divider and the shunt and receiving the connection signal, so as to provide the switch signal according to the connection signal, the phase reference voltage, and the phase reference current.

5. The system as recited in claim 4, wherein the control unit further comprises:
a power circuit receiving the alternating current voltage to provide a direct current operating voltage to the control circuit.

6. The system as recited in claim 1, wherein the switch unit comprises a relay.

7. The system as recited in claim 1, further comprising a fuse coupled between the switch unit and the first power interface.

8. The system as recited in claim 1, wherein the first power interface and the second power interface are coupled to a first ground point, the control unit is coupled to a second ground point, the first ground point is different from the second ground point, and the second ground point is coupled to a ground wire configured to transmit the alternating current voltage.

9. The system as recited in claim 1, wherein the second power interface is an insertion terminal of an outlet, and the first power interface is a plug.

10. The system as recited in claim 1, wherein the second power interface is an insertion terminal of an outlet, and the first power interface is a circuit terminal of the outlet.
